(19) United States
(12) Patent Application Publication
(10) Pub. No.: US 2014/0183066 A1
(43) Pub. Date: Jul. 3, 2014

(54) Cover for Mobile Telephone

(71) Applicant: Graphique de France, Ltd., Woburn, MA (US)

(72) Inventor: Jean-Jacques Toulotte, Woburn, MA (US)

(73) Assignee: Graphique de France, Ltd., Woburn, MA (US)

(21) Appl. No.: 14/181,254

(22) Filed: Feb. 14, 2014

Related U.S. Application Data
(63) Continuation-in-part of application No. 14/143,291, filed on Dec. 30, 2013.
Application No. 14/143,291 is a continuation-in-part of application No. 29/440,991, filed on Dec. 28, 2012.
(60) Provisional application No. 61/756,884, filed on Jan. 25, 2013.

(51) Int. Cl. H05K 5/03

(52) U.S. Cl. CPC H05K 5/03
USPC 206/37

(57) ABSTRACT

A cover for a mobile telephone, such as a smartphone, is provided. The cover includes a front board, a back board, and a spine that hingedly attaches to the front board and the back board. These three components cooperate to cover three sides of the mobile telephone. A cradle assembly affixed to the interior surface of the back board releasably grips the mobile telephone. A flap is hingedly attached to the front board and provides attachment means for removably attaching the flap to an exposed portion of the mobile telephone. The attachment means may optionally be magnetic, and attach to a magnetic portion of the mobile telephone. A portion of the flap material may be slip-resistant to permit the cover to assume a stable, inclined configuration in which a portion of the weight of the mobile telephone on the flap material prevents slippage.

### CROSS-REFERENCE TO RELATED APPLICATIONS

This application is a continuation-in-part of U.S. application Ser. No. 14/143,291, filed Dec. 30, 2013. Application Ser. No. 14/143,291 claims the benefit of U.S. Provisional Application No. 61/756,884, filed Jan. 25, 2013, and is a continuation-in-part of U.S. Design application Ser. No. 29/440,991, filed Dec. 28, 2012. The entire contents of the above applications are incorporated herein by reference.

### TECHNICAL FIELD

The present invention relates to telephonic communications, and more particularly to an accessory for a mobile telephone terminal that provides a protective structure that releasably grips the terminal and may be folded into a variety of useful operating configurations.

### BACKGROUND ART

People often desire to use covers for their portable handheld electronic devices, especially for their cellular phones. Reasons for using covers include protection of the device, improvement of the appearance of the device, incorporation of a certain fashionable look over the device, and generation of variety in the way the device looks.

The available phone covers have been designed with goals similar to those above in mind; however, upon careful testing, previously unappreciated disadvantages often manifest themselves. For example, a part of the cover may inappropriately dangle after opening the cover; it may be difficult to use the phone without holding it in a hand; the positions that the phone can be used with the cover may be limited; certain features may be inaccessible in certain positions of the cover; or the fit between the phone and the phone cover may be weak or insecure. Therefore, there is a need to develop a phone cover that achieves maximal functionality with a professional design, which simultaneously streamlines the usage of the phone in different positions.

### SUMMARY OF ILLUSTRATED EMBODIMENTS

Illustrated embodiments of the present invention enable a user to use a mobile phone in multiple positions with ease. For example, in a closed position, the phone cover can cover the phone when greater protection is needed or when the phone is not being used. In an open position, the phone can be used with full functionality and without superfluous interfering parts, as the lower and upper parts of the phone cover can be compacted behind the phone and further stabilized by magnetism. In a supported-open position, the phone can be used without needing to free hands from other tasks. Disclosed openings of the phone cover enable functionality of various features of the phone without a need for removal of the phone cover. A magnetic fastening mechanism between the phone and the phone cover results in an integrated phone and phone cover that cooperate as a unit. Such integration makes the whole assembly more durable and less prone to slippage. The functional design ensures that there are no superfluous parts, resulting in a satisfying user experience. The integration between the phone cover and the phone, especially when such integration ensues from a distinctly positioned magnet of the flap and a magnet phone-anchor on a distinct side of the phone, ensures that the orientations of the phone and the phone cover are consistent and predictable. This prevents cases in which a user may open the phone cover to answer a call and find out that the phone is upside down, contrary to what would have been desirable.

Therefore, an embodiment of the invention provides a cover for a mobile telephone. The cover includes a front board having an interior surface and an exterior surface. The cover also includes a back board having an interior surface and an exterior surface. The cover has a spine that is hingedly attached to the front board along a front-spine hinge and hingedly attached to the back board along a back-spine hinge. The front-spine hinge is parallel to the back-spine hinge. In a closed configuration of the cover, the interior surface of the back board faces the interior surface of the front board, and in an open configuration the exterior surface of the back board faces the exterior surface of the front board. The cover further includes a cradle assembly having a front and a back. The front of the cradle assembly is configured to releasably grip the mobile telephone and the back of the cradle assembly is affixed to the interior surface of the back board. The cover also has a flap hingedly attached to the front board along a front-flap hinge that is parallel to the front-spine hinge. Finally, the cover includes attachment means for removably attaching the flap to a portion of the mobile telephone while the mobile telephone is releasably gripped by the front of the cradle assembly, the cradle assembly having an opening for exposing the portion of the mobile telephone to the attachment means.

The basic cover of the foregoing embodiment may be made from different materials. For example, the front board, the back board, and the spine may be made from paperboard or plastic foam. Each hinge attachment may be made from paper. The cradle assembly may be formed from injection-molded plastic. The attachment means may include a magnet disposed in the flap, so that when the magnet is aligned with the opening in the cradle assembly in the closed configuration, a magnetic attraction is produced that is sufficient to resist relative movement between the rigid flap and the mobile telephone. In other embodiments, the attachment means comprise a mechanical stopper, a clasp, a rivet, or an adhesive.

The cover may include a liner that conceals the front board, the back board, the spine, and the flap. The liner may be made from fabric. An exterior surface of the liner may be decorated with a pattern, a logo, or a pleasing image. Advantageously, a portion of the liner that conceals the flap may be made from a slip-resistant material, so that the cover is capable of assuming a stable, weight-supported configuration in which an angle of inclination is preserved at least in part due to a portion of the weight of a releasably gripped mobile telephone on the slip-resistant material acting to prevent relative motion of the front board and the back board.

### BRIEF DESCRIPTION OF THE DRAWINGS

The foregoing and other objects, features, and advantages of the invention will be apparent from the following more particular description of preferred embodiments of the invention, as illustrated in the accompanying drawings in which parts are referred to by reference characters across views. The drawings are not necessarily to scale, emphasis instead being placed on illustrating the principles of the invention.

FIG. 1 is perspective view of a phone cover, in accordance with an embodiment of the present invention, in an open configuration with a phantom view of a phone cradled in the cover.

FIG. 2 is a front elevation view of the phone cover of FIG. 1, also in an open configuration, showing the inner sides of the phone cover.

FIG. 3 is a rear elevation view of the phone cover of FIG. 1, in an open configuration, showing the outer sides of the phone cover.

FIG. 4 is a left side elevation view schematic of the phone cover of FIG. 1.

FIG. 5 is a perspective view showing the phone cover of FIG. 1 in a closed configuration.

FIG. 6A is perspective view of the phone cover of FIG. 1 in a nearly closed configuration.

FIG. 6B is a perspective view of the phone cover of FIG. 1 in an open configuration, which allows a user to talk on the phone without an interruption from a moving part, since the lower and upper portions of the phone cover are held in place by the use of a magnet and a magnet phone anchor.

FIG. 6C is a perspective view of the phone cover of FIG. 1 in a weight-supported configuration, which enables a user to rest the phone with the phone cover on a supporting surface, such as a desk, and use the phone in a hands-free manner.

FIG. 7A is a perspective view of the phone cover of FIG. 1 that has been modified to include a first decorative pattern including a message imprinted onto the surface of the upper-outer side of the phone cover.

FIG. 7B is a perspective view of the phone cover of FIG. 1 that has been modified to include a second decorative pattern including a message imprinted onto the surface of the upper-outer side of the phone cover.

FIG. 7C is a perspective view of the phone cover of FIG. 1 that has been modified to include a third decorative pattern imprinted onto the surface of the upper-outer side of the phone cover.

FIG. 7D is a perspective view of the phone cover of FIG. 1 that has been modified to include a fourth decorative pattern including a message imprinted onto the surface of the upper-outer side of the phone cover.

FIG. 8 is a schematic diagram showing a rear elevation of an alternate embodiment of the phone cover, in an open configuration, that includes a speaker cutout.

FIG. 9 is left side elevation view of a phone cover embodiment.

### DETAILED DESCRIPTION OF SPECIFIC EMBODIMENTS

The present invention relates to covers for mobile telephones, such as smartphones. Various embodiments of the present invention enable a user to protect a phone, and to use a phone in different positions in an efficient way. The overall design of the phone cover is appealing and presents a unified interplay between optimized utility of different parts and displayed aesthetics of the phone cover.

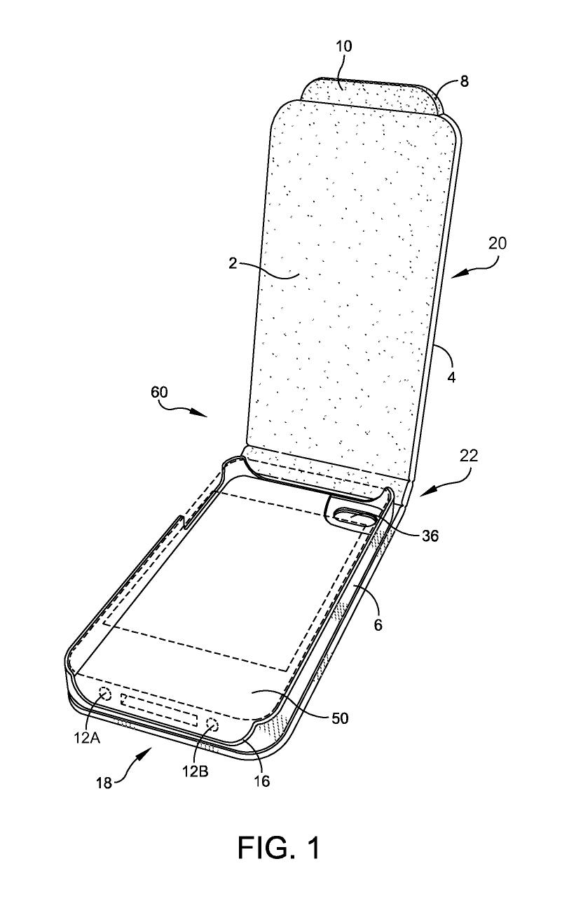

FIG. 1 is perspective view of a phone cover, in accordance with an embodiment of the present invention, in an open configuration with a phantom view of a phone cradled in the cover. Referring to FIG. 1, phone 50 (shown in dashed outline) is covered by phone cover 60. Phone cover 60 has an optional liner 2, a support member 4, a cradle assembly 6, and a flap 8 having attachment means 10. These components and their respective operating principles are now described in detail.

Liner 2, as shown in FIG. 1, is attached to support member 4. The liner 2 may provide a pleasing visual and tactile experience for a user of the phone cover 60, and may protect the support member 4. The liner can be made of different types of fabric, such as felt or a microfiber. Examples of other fabrics that the liner can be made from include cotton, linen, silk, wool, hemp, ramie, jute, rayon, and spandex.

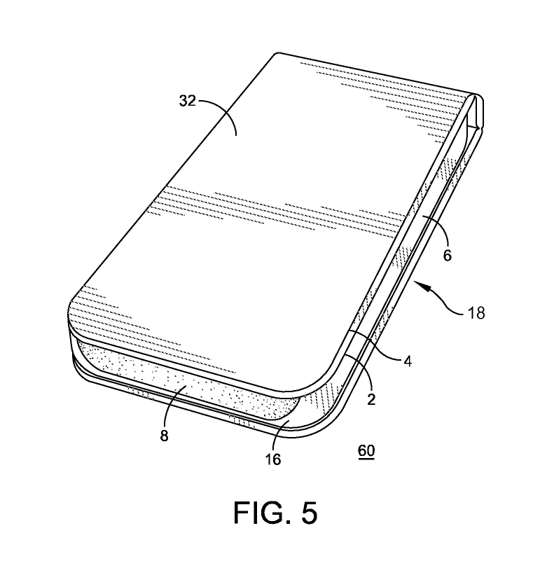

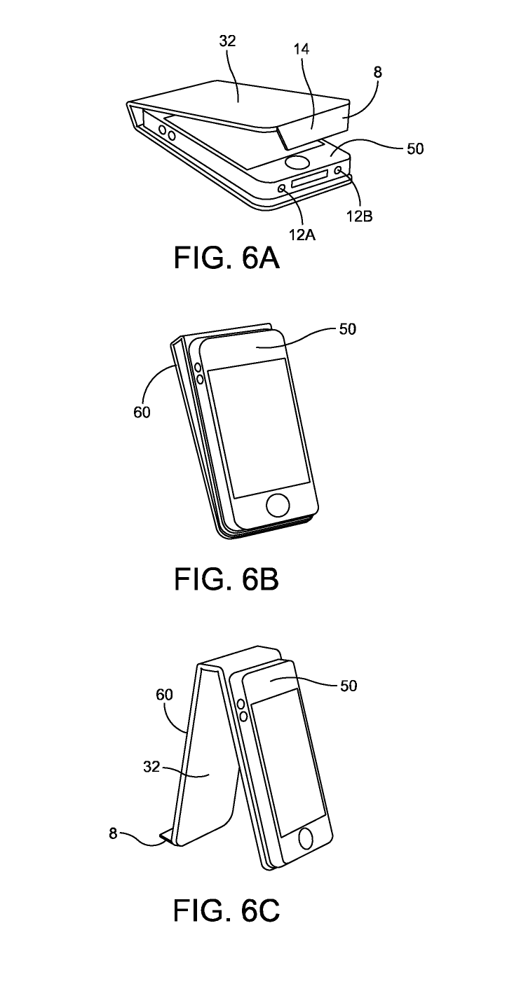

The support member 4 supports the weight of the phone 50 in various configuration when the phone 50 is installed in the cradle assembly 6. The support member 4 includes a back board 18, to the interior surface of which is affixed the cradle assembly 6. The support member 4 also includes a front board 20 that covers the phone 50 when the cover 60 is closed. Finally, the support member 4 includes a spine 22 that attaches the back board 18 to the front board 20 using two hinges. The use of hinged attachments permits the cover 60 to assume at least four different configurations at the desire of a user, as shown in FIGS. 5 and 6A-6C and described in more detail below.

The support member 4 shown in FIG. 1 also includes a viewport opening 36, which allows a camera component of the phone to be used without needing to take the phone cover off. This viewport opening 36, or other similar openings, can be created by simply manufacturing the support member 4 (and other potentially interfering parts such as the liner 2) with an opening, or by cutting open the holes with a puncher or a more specialized device.

Cradle assembly 6 is designed to releasably grip the phone 50. The back of the cradle assembly 6 is affixed to an interior surface of the back board 18. In FIG. 1, cradle assembly 6 has a flap opening 16 that exposes a bottom portion of the phone 50 to flap 8 and attachment means 10 in various open and closed positions of the phone cover 60. The shape of the flap opening 16 and the flap 8 are generally complementary to each other so that once the phone cover is closed, no substantial gaps are left in the flap opening 16, and the flap 8 and the parts of the cradle assembly 6 extending from the flap opening 16 form a generally continuous area. One example of this complementarity is seen in FIG. 5, wherein the edges of the flap 8 are substantially touching the edges of the flap opening 16. The cradle assembly 6 is used to secure the phone 50 in place. In various embodiments, the cradle assembly 6 is somewhat deformable, and is slightly deformed when the phone is inserted therein so as to frictionally grip the phone. The act of securing, although technically referring to that of between the phone 50 and the cradle assembly 6, can also be used to refer to that between the phone 50 and the phone cover 60.

The support member 4, the cradle assembly 6, or both can be made from a plastic material, such as injection-molded plastic. In some embodiments, the plastic can be a transparent material, a translucent material, or a combination of both. In alternative embodiments, the support member 4, the cradle assembly 6, or both have one or more transparent portions; in others, it is entirely transparent. The support member 4 and its component back board 18, front board 20, and spine 22 also may be made of other materials such as paperboard or plastic foam. The hinges and hinge attachments may be made from paper. Different such materials may be used in the construction of the cover 60 to provide different properties, such as high strength, long durability, low weight, low manufacturing cost, and other properties desirable to a manufacturer, retailer, or end user.

The support-member 4 and the cradle assembly 6 can be manufactured from any of the materials mentioned above via a variety of methods. For example, injection molding can be used. Injection molding can introduce a plastic into a specially designed mold where the heated plastic would take the shape of an object with specifically desired dimensions and features. The mold retains its shape at the temperatures that transform the plastic; some examples of materials that satisfy this criterion for the mold include steel and aluminum.

Flap 8 is included in the phone cover 60 to permit the cover to securably close. In a closed configuration, the flap 8 fits into the flap opening 16 of the cradle assembly 6. Attachment means 10 in or near the flap 8 then secures either the phone 50 or the cradle assembly 6 to the flap 8, which is itself attached to the front board. In this way, the entire cover 60 can be stably held in a closed configuration, thereby preventing accidental manipulation of the controls of the phone 50 or damage to the phone 50. In the embodiment shown in FIG. 1, flap 8 has been incorporated as an extension of the liner 2. In other embodiments, the flap 8 can be attached to the liner 2, or it can be attached to the support member 4.

The flap 8 can be made from the same set of materials that the liner 2 is made from, for example microfiber. The flap 8 can be used to fasten the phone cover 60 in a closed configuration in which the interior surface of the back board faces the interior surface of the front board. The flap 8 also can be used to fasten the phone cover 60 in an open configuration in which the exterior surface of the back board faces the exterior surface of the front board. The flap 8 can also be disengaged from the flap opening 16 to unfasten the phone cover 60. This fastening and unfastening of the phone cover 60 results from an attachment and detachment of the attachment means 10.

The attachment means 10 is used for removably attaching the flap 8 to a portion of the phone 50 while the phone 50 is releasably gripped by the front of the cradle assembly 6. The attachment means 10 can be embedded in the entire length of the flap 8 or in a portion of it. The attachment means 10 can be substantially closer to one side, to another side, or be about equal distance from either side.

A magnet is one example of attachment means 10. In this example, the phone includes ferromagnetic material that is proximate to the flap 8, when the flap is disposed in the flap opening 16, such as provided by steel screws 12A and 12B at the base of various models of an iPhone® phone, available from Apple Inc., Cupertino, Calif. The attraction of the magnet to the screws 12A and 12B releasably secures the flap 8 in the flap opening 16, and ordinary manipulation by the user can readily dislodge the flap 8 from the flap opening 16 to provide user access to the phone. Orienting the phone with the screws 12A and 12B facing the flap 8 when the flap is closed results in a consistent conformation of the phone 50 in relation to the phone cover 60, so that when a user quickly opens up the phone cover to answer a call, there is no need to waste additional time to determine the orientation of the phone or to readjust the phone. For a phone lacking ferromagnetic material at the locations of screws 12A and 12B, the cradle assembly 6 may be modified (i) to cause the wall generally surrounding the phone to partially fill the flap opening 16 so as to cover the locations at screws 12A and 12B and (ii) to include ferromagnetic material at such locations. The support member 4 including the flap 8 may be correspondingly modified, so that the flap is releasably attachable to the cradle assembly 6.

It will be appreciated that attachment means 10 other than a magnet may be used to secure the flap 8. For example, a mechanical stopper may insert into a port in the bottom of the phone 50 to secure the flap 8. Alternately, the attachment means 10 may include a clasp that releasably couples with the edge of the flap opening 16. A snap-and-rivet system may also be used as attachment means 10. Or, the attachment means 10 may include hook and loop material mounted on the surfaces to be releasably attached or alternatively a weak or moderate strength adhesive that bonds to the phone 50 or cradle assembly 6 with a strength that is easily broken by humans. A person having skill in the art may envision other such attachment means 10 adaptable for use to secure the flap 8 in the flap opening 16, thereby closing the phone cover 60.

The phone 50 shown in FIG. 1 has magnet phone-anchors 12A and 12B. These magnet phone-anchors 12A, 12B can be any magnetic material. In some models of the APPLE IPHONE® phone (such as 4, 4S and 5), there are two steel screws at the bottom side of the phone that are ferromagnetic. These two screws can serve as the magnet phone-anchors described herein. Any other part or parts of phones, which can be on the surface or inside, and which can be visible or not, that are of magnetic material can serve as the magnet phone-anchors (e.g., battery, charging slot, camera parts, external surface material, stylus pen, stylus pen slot). Utilization of a magnetic attraction between magnet phone-anchors 12A, 12B on the bottom side of the phone 50 and a magnet of the phone cover 60 is a unique feature of certain embodiments of the present invention; however, it is possible to use the phone cover 60 of the present invention with phones that have alternative arrangements of magnet phone-anchors 12A, 12B, including those with additional magnet phone-anchors on other sides.

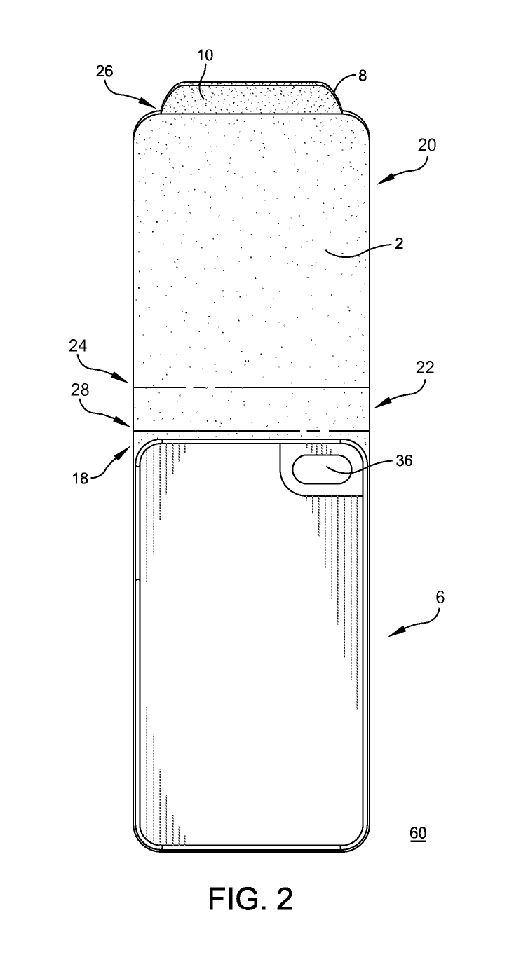

FIG. 2 is a front elevation view of the phone cover of FIG. 1, also in an open configuration, showing the inner sides of the phone cover. The liner 2, cradle assembly 6, flap 8, attachment means 10, back board 18, front board 20, and spine 22 are indicated. Also indicated are three hinges. A front-spine hinge 24 attaches the front board 20 to the spine 22. A front-flap hinge 26 attaches the front board 20 to the flap 8. A back-spine hinge 28 attaches the back board 18 to the spine 22. The use of the spine hinges 24, 28 permits the cover to assume a closed configuration, a partially closed configuration, a locked open configuration, and a weight-supported configuration, as described below in connection with FIGS. 5, 6A, 6B, and 6C respectively. The use of the flap hinge 26 permits the locking of the locked open configuration of FIG. 6B. Viewport opening 36 is shown to be formed from portions of the back board 18 and an area near an edge of the cradle assembly 6. The viewport opening 36 can be at a different part of the phone cover, depending on where the camera is. In some embodiments, there is more than one opening to enable usage of more than one camera.

The hinges 24, 26, 28 can be made from the same material as the support member 4, or from a different material such as paper. For example, in some embodiments, the hinge is made out of plastics such as polypropylene or polyethylene. The hinge can be made, in alternative embodiments, by various methods including designing the molding process to make the hinge area thinner, by scoring, by coining, or by a combination thereof.

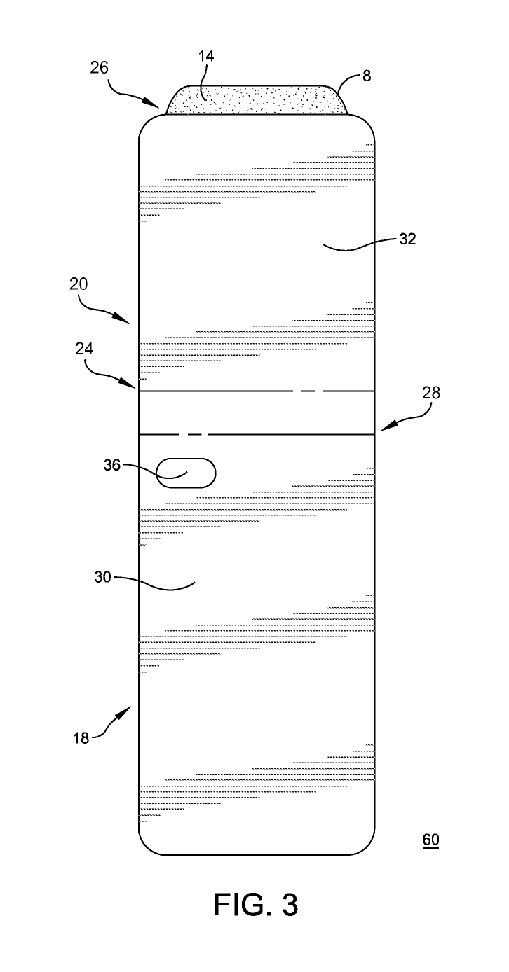

FIG. 3 is a rear elevation view of the phone cover of FIG. 1, in an open configuration, showing the outer sides of the phone cover. FIG. 3 shows flap exterior material 14, back board exterior surface 30, and front board exterior surface 32, in addition to a subset of the parts already described. The flap exterior material 14 is a part of the flap that functions as a high friction, slip-resistant surface to stabilize the phone cover 60 in a weight-supported configuration. The flap exterior material 14 can be on either side of the flap 8 or on only one side of the flap 8. In a certain embodiment, the attachment means 10 are located near the inner side of the flap 8, and the flap exterior material 14 is located near the outer side of the flap 8. In other embodiments the attachment means 10 are substantially equally effective on both sides, and in alternative embodiments the flap exterior material 14 is substantially equally effective on both sides.

The flap exterior material 14 can be made from any material that exhibits a frictional coefficient sufficient to keep the phone cover in a weight-supported configuration when it is loaded with a phone. Examples of such materials include rubbers (natural, synthetic, vulcanized, and/or elastomeric ones). A particular example comprises silicones (i.e., polysiloxanes, polymerized siloxanes), which are materials that combine silicon with other atomic elements such as carbon, oxygen, and hydrogen. Other examples of flap external material 14 include polybutadiene, styrene-butadiene, nitrile rubber, neoprene, latex, and polyisoprene.

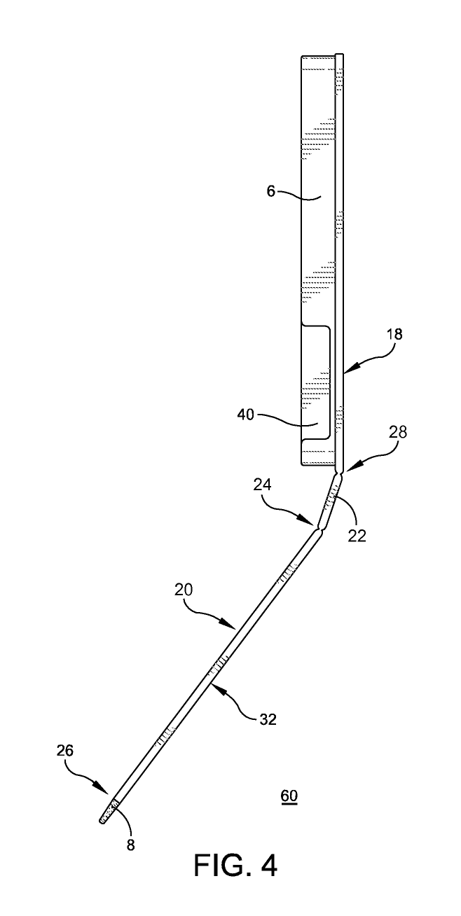

FIG. 4 is a left side elevation view schematic of the phone cover of FIG. 1. FIG. 4 shows a control opening 40 in addition to several of the parts described in more detail above. As can be seen from this Figure, the spine 22 and the spine hinges 24, 28 enable the phone cover 60 to take different positions. For example, it allows the phone cover to be opened, closed, and put into a weight-supported configuration. In some embodiments, the spine 22 is made from the same material as the back board 18 and the front board 20, while in others it is made from a differing material. The control opening 40 allows access to various controls of a gripped phone 50. For example, it can allow adjustment of volume controls near a side of the phone.

FIG. 5 is a perspective view showing the phone cover of FIG. 1 in a closed configuration, and depicts the fit between the flap 8 and flap opening 16. In the figure, different shadings have been employed to distinguish these two parts; however, in some embodiments the color, texture, material, or a combination thereof of these two parts can be substantially similar so as to display a continuous surface at the same area. In embodiments that have a particularly precise complementarity between the flap 8 and the flap opening 16, the functional design of the phone cover 60 is especially apparent.

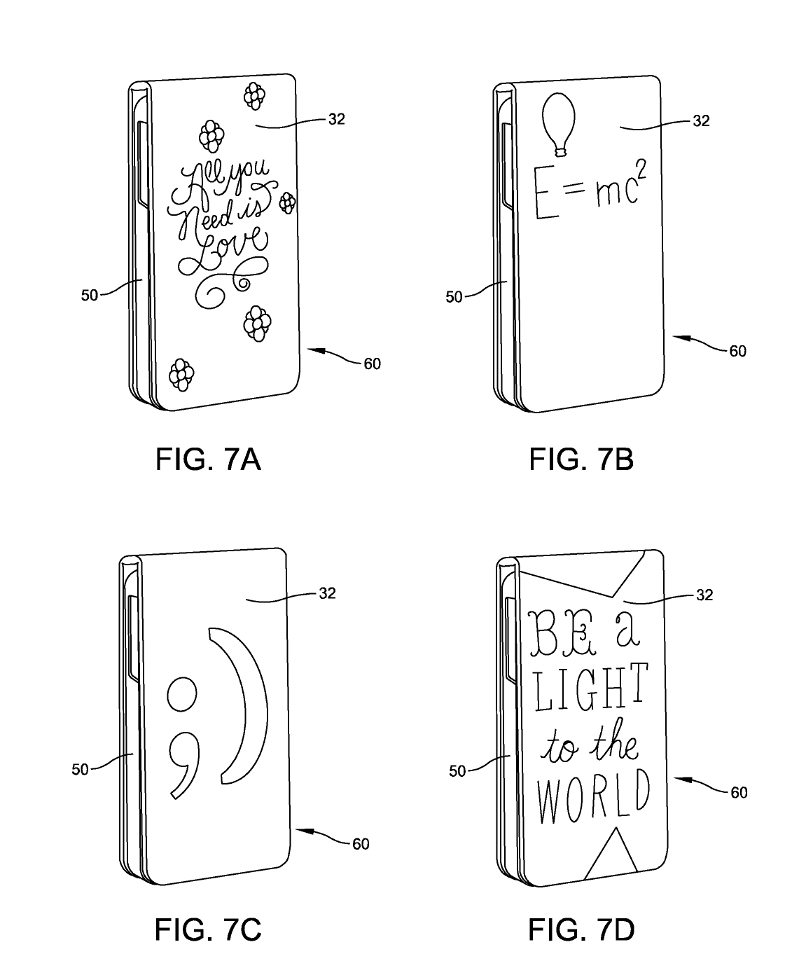

Another seamless integration between parts in FIG. 5 is that between support member 4 and liner 2. In an embodiment, these two parts can be made to look different or similar. In certain embodiments, the support member 4 further includes two layers, one on the inner side and the other on the outer side. These two layers can be made from the same material or from different materials. In one embodiment, the outer layer is made from polyurethane and the inner layer is made from polypropylene. In some embodiments, one or more of the surfaces or parts of the surfaces can be dyed to a different color than the remaining parts or surfaces; examples are given below in connection with FIGS. 7A-7D. The layers can be merged together by the use of adhesives, such as glues, or by the use of stitches. Any other method known or developed later can be used, as long as it serves to join the layers together.

FIGS. 6A, 6B, and 6C show other configurations of the phone cover 60. FIG. 6A depicts a configuration of the phone cover 60 that is partially open (or partially closed). Shown is the flap 8 with flap exterior material 14 facing outward, and the attachment means 10 (not shown) approaching magnet phone-anchors 12A and 12B of phone 50. This configuration may be used advantageously, for example, to take a picture using a camera feature of the phone 50.

FIG. 6B depicts an open position of phone cover 60 with phone 50 held in place by a cradle assembly 6. The ability to fold the front board toward the back board and secure it in place enables a user to use the phone 50 without distraction from an unstable phone cover 60. In this embodiment, the front board is further stabilized behind the phone 50 via the use of the attachment means 10 (not shown). For example, a magnet in the flap 8 can fasten to a magnet phone-anchor 12A, 12B from both the front side of the phone (as shown in FIG. 5) and the back side of the phone (in the configuration of FIG. 6B).

FIG. 6C depicts a weight-supported configuration of the phone cover 60, with phone 50 held by the cradle assembly 6 (not shown). The flap 8 has its flap exterior material 14 facing the surface on which the phone 50 and phone cover 60 are resting, so the weight of the phone 50 on the slip-resistant material 14 acts to stabilize the phone cover by preventing relative motion of the front board and the back board. This configuration enables a user to use the phone 50 hands-free, for example by placing the phone 50 and phone cover 60 onto a desk or table. From this position, a user can activate a front side camera of the phone and interact with another user by talking on the phone while also visually interacting with the other user. An example software that facilitates this type of interaction is FACETIME™ software available from Apple Inc., Cupertino, Calif. In an embodiment, the spine hinges 24, 28 can be angled such that the interior surface of the spine 22 is facing the user. This interior surface can be used for advertising, pictures, phrases, quotes, drawings, pictures, symbols, or any other artistic expressions. Each of the configurations of FIGS. 5 and 6A-6C can be thought of as members of a family of related configurations.

FIGS. 7A, 7B, 7C, and 7D show different designs that can be applied to the front board exterior surface 32. The designs can include pictures, phrases, quotes, drawings, pictures, symbols, or any other artistic expressions. Such designs can be displayed on either or both of the front board exterior surface 32 and the back board exterior surface 30. In one embodiment, personal imagery is displayed on the front board side, whereas more generic advertisement imagery is displayed on the back board side. The front board exterior surface 32 and/or the back board exterior surface 30 can be used for advertisements, and/or displaying brands and logos. Artistic imagery refers to any visual representation applied to these surfaces, from a plain paint with a monochrome dye to anything more sophisticated.

A phone cover with a support member, a cradle assembly, a liner, and a flap has been constructed. The flap was made from microfiber and attached to the top portion of the liner, which was also constructed from a microfiber. The magnet used in the phone cover was custom made, having the following magnetic field properties: minimum 1500 gauss; maximum 2000 gauss. The support member was manufactured from two materials making up an inner layer and an outer layer. The inner layer, the one closer to the phone, was made from polypropylene. The outer layer was made from polyurethane. These separate layers were merged and sealed. The cradle assembly was manufactured from injection-molded plastic. Openings (for the camera and the volume controls) in the support member and the cradle assembly were made using standard practices. Silicone was incorporated into one of the sides of the flap—the side that faces away from the bottom of the phone when the phone cover is in a closed position—to increase the frictional properties of the flap when the phone cover is in a supported-open position.

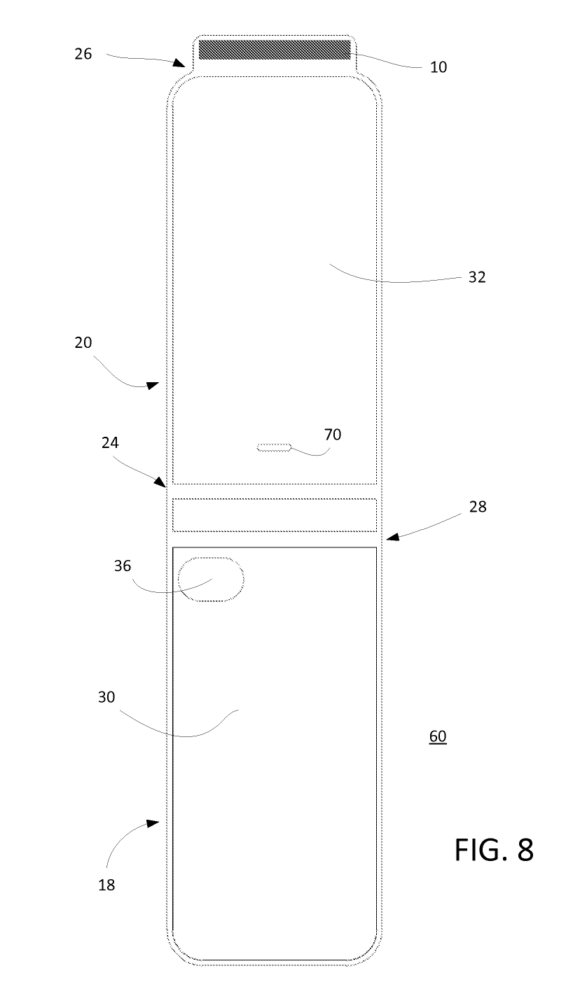

Certain models of mobile telephones include a speaker on the front for listening to other call participants, music, or other sounds produced by the telephone. However, when a typical cover is placed around a mobile telephone, this speaker is muffled, producing sound output of an inferior quality. FIG. 8 is a schematic diagram showing a rear elevation of an alternate embodiment of the phone cover 60, in an open configuration, that includes a speaker cutout 70. The speaker cutout 70 advantageously may be positioned to expose the speaker of the mobile telephone while the telephone is releasably gripped by the front of the cradle assembly 6 and the cover 60 is in a closed configuration, thereby addressing this problem. The speaker cutout 70 in the front board 20 penetrates the front board exterior surface 32 and the front board interior surface, and has a sufficient size, shape, and position to provide an unobstructed path for any sound emitted by the speaker to reach the space outside of the closed cover 60, thereby avoiding any undesired attenuation effects or muffling of the audio output. The exterior surface of the liner 2 may include pattern, a logo, or a pleasing image that disguises the appearance of the cutout, which would otherwise serve to break up the uniformity and harmony of the external appearance of the closed cover.

FIG. 8 also shows the attachment means 10, depicted here as a magnet, that is inside the flap exterior material 14 (not shown). The attachment means 10 may be a magnet oriented and sized to releasably couple to a surface of a mobile phone when gripped by the cradle assembly 6. For example, the magnet may have its negative or north pole facing outward, and have a size that is approximately 42.0×5.0×1.5 mm. Because the mobile telephone microphone may be located in the vicinity of the attachment means 10 (when the cover is in a closed configuration), the placement of the magnet within the flap 8 may advantageously be made to expose the microphone to the environment even when the cover is closed, thereby reducing any undesired attenuation effects or muffling of the audio input.

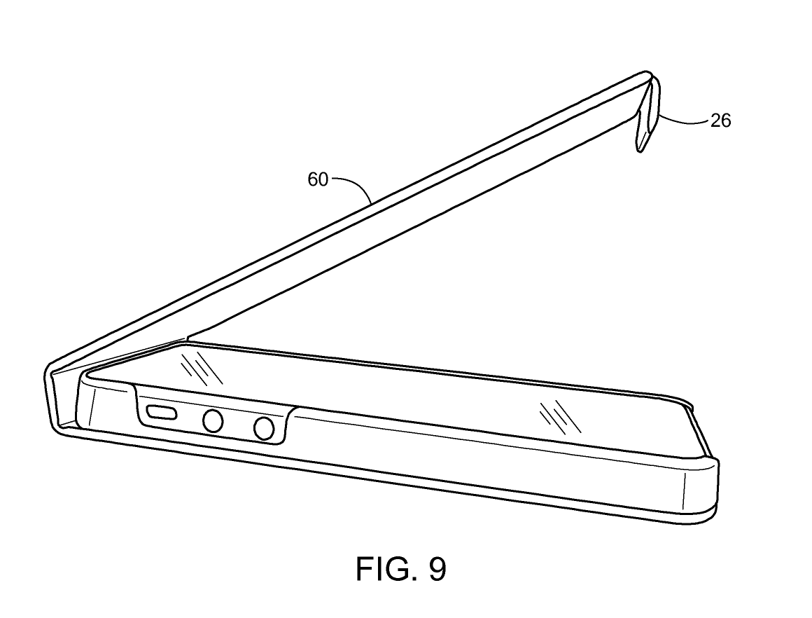

The ability of the attachment means 10, such as the magnet described above, to fasten the front board 20 to the mobile telephone may be enhanced by a judicious choice of the angle that the flap 8 makes with respect to the front board 20. The front board 20 must extend at least to, if not beyond, the edge of the cradle assembly 6 in order for the flap 8 to be angled so as to present the attachment means 10 to the mobile telephone. If the front board 20 is too short, the attachment means 10 cannot be adjusted to reach the mobile telephone because the bottom edge of the cradle assembly 6 will physically obstruct placement of the flap 8. Therefore, it is preferable to manufacture the front board 20 to err on the side of excess length. However, if the front board 20 extends past the edge of the cradle assembly 6, then the front-flap hinge 26 must make an acute angle to present the attachment means 10 to the mobile telephone. Given existing manufacturing tolerances and the expectation that the front board 20 will extend beyond the bottom edge of the cradle assembly 6, in one embodiment of the invention the front-flap hinge 26 is manufactured with a physical bias to favor retention of an acute angle substantially between 80 degrees and 89 degrees when the cover 60 is in the closed position. This physical bias facilitates coupling of the attachment means 10 to the mobile phone during the process of closing the cover 60 by naturally guiding the attachment means 10 to its eventual resting position. FIG. 9 is left side elevation view of a phone cover embodiment showing a cover 60, at rest in a partially-closed configuration, having its front-flap hinge 26 showing a natural propensity to retain an angle of substantially between 80 degrees and 89 degrees.

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. A cover for a mobile telephone, the cover comprising:
a front board having an interior surface and an exterior surface;
a back board having an interior surface and an exterior surface;
a spine that is hingedly attached to the front board along a front-spine hinge and hingedly attached to the back board along a back-spine hinge, the front-spine hinge being parallel to the back-spine hinge, so that in a closed configuration of the cover, the interior surface of the back board faces the interior surface of the front board, and in an open configuration the exterior surface of the back board faces the exterior surface of the front board;
a cradle assembly having a front and a back, wherein the front of the cradle assembly is configured to releasably grip the mobile telephone and the back of the cradle assembly is affixed to the interior surface of the back board;
a flap hingedly attached to the front board along a front-flap hinge that is parallel to the front-spine hinge; and
attachment means for removably attaching the flap to a portion of the mobile telephone while the mobile telephone is releasably gripped by the front of the cradle assembly, the cradle assembly having an opening for exposing the portion of the mobile telephone to the attachment means,
wherein the front board includes a cutout that exposes a speaker of the mobile telephone while (1) the mobile telephone is releasably gripped by the front of the cradle assembly and (2) the cover is in the closed configuration.

2. A cover according to claim 1, wherein the front board, the back board, and the spine comprise paperboard or plastic foam.

3. A cover according to claim 1, further comprising a fabric liner that conceals the front board, the back board, the spine, and the flap.

4. A cover according to claim 3, wherein an exterior surface of the liner is decorated with a pattern, a logo, or a pleasing image that disguises the appearance of the cutout.

5. A cover for a mobile telephone, the cover comprising:
a front board having an interior surface and an exterior surface;
a back board having an interior surface and an exterior surface;
a spine that is hingedly attached to the front board along a front-spine hinge and hingedly attached to the back board along a back-spine hinge, the front-spine hinge being parallel to the back-spine hinge, so that in a closed configuration of the cover, the interior surface of the back board faces the interior surface of the front board, and in an open configuration the exterior surface of the back board faces the exterior surface of the front board;
a cradle assembly having a front and a back, wherein the front of the cradle assembly is configured to releasably grip the mobile telephone and the back of the cradle assembly is affixed to the interior surface of the back board;
a flap hingedly attached to the front board along a front-flap hinge that is parallel to the front-spine hinge; and
attachment means for removably attaching the flap to a portion of the mobile telephone while the mobile telephone is releasably gripped by the front of the cradle assembly, the cradle assembly having an opening for exposing the portion of the mobile telephone to the attachment means,
wherein the front-flap hinge is constructed to favor retention of an acute angle of substantially between 80 degrees and 89 degrees when the cover is in the closed position.

6. A cover according to claim 5, wherein each hinge attachment comprises paper.

7. A cover according to claim 6, wherein the attachment means comprises a magnet disposed in the flap, and wherein the portion of the mobile telephone is magnetic, so that when the magnet is aligned with the opening in the cradle assembly in the closed configuration according to the favored acute angle, a magnetic attraction is produced that is sufficient to resist relative movement between the rigid flap and the mobile telephone.

8. A cover for a mobile telephone, the cover comprising:
a front board having an interior surface and an exterior surface;
a back board having an interior surface and an exterior surface;
a spine that is hingedly attached to the front board along a front-spine hinge and hingedly attached to the back board along a back-spine hinge, the front-spine hinge being parallel to the back-spine hinge, so that in a closed configuration of the cover, the interior surface of the back board faces the interior surface of the front board, and in an open configuration the exterior surface of the back board faces the exterior surface of the front board;
a cradle assembly having a front and a back, wherein the front of the cradle assembly is configured to releasably grip the mobile telephone and the back of the cradle assembly is affixed to the interior surface of the back board;
a flap hingedly attached to the front board along a front-flap hinge that is parallel to the front-spine hinge; and
attachment means for removably attaching the flap to a portion of the mobile telephone while the mobile telephone is releasably gripped by the front of the cradle assembly, the cradle assembly having an opening for exposing the portion of the mobile telephone to the attachment means,
wherein the attachment means comprises a magnet disposed in the flap, the magnet being positioned to expose a microphone of the mobile telephone while simultaneously producing a magnetic attraction that is sufficient to resist relative movement between the rigid flap and the mobile telephone when (1) the mobile telephone is releasably gripped by the front of the cradle assembly and (2) the cover is in the closed configuration.

9. A cover according to claim 8, wherein the negative pole of the magnet is facing outward.
